(19) United States
(12) Patent Application Publication
(10) Pub. No.: US 2024/0077521 A1
(43) Pub. Date: Mar. 7, 2024

(54) CURRENT MEASUREMENT MODULE, CURRENT MEASUREMENT CONDUCTOR, AND CURRENT MEASUREMENT DEVICE

(71) Applicant: Asahi Kasei Microdevices Corporation, Tokyo (JP)

(72) Inventor: Kenji KURIYAMA, Tokyo (JP)

(21) Appl. No.: 18/460,592

(22) Filed: Sep. 4, 2023

(30) Foreign Application Priority Data
Sep. 7, 2022 (JP) 2022-142280
Jul. 19, 2023 (JP) 2023-117632

(51) Int. Cl. G01R 19/00; G01R 33/09

(52) U.S. Cl. CPC G01R 19/0092; G01R 33/091

(57) ABSTRACT

Provided is a current measurement module including: a conductor which has two main body portions and two current paths disposed between the two main body portions and extending in parallel with a gap; two magnetic field sensing elements which each have a magnetosensitive surface disposed such that magnetic fields generated by current flowing through the two current paths penetrate the magnetosensitive surface in directions opposite to each other; and a substrate which supports the two magnetic field sensing elements and is attached to the conductor, the two main body portions each have a slit which extends from the gap and is narrower than the gap, and the substrate is inserted into the slit and the gap.

### BACKGROUND

### 1. Technical Field

The present invention relates to a current measurement module, a current measurement conductor, and a current measurement device.

The contents of the following Japanese patent application(s) are incorporated herein by reference:
NO. 2022-142280 filed in JP on Sep. 7, 2022
NO. 2023-117632 filed in JP on Jul. 19, 2023

### 2. Related Art

Patent Document 1 discloses “a current measurement device and a current measurement method for measuring a magnitude of current flowing through two to-be-measured current conductors placed in parallel to a longitudinal direction”. Patent Document 2 discloses “a current detection device and a current detection method for detecting a current flowing through a current path using a magnetic field sensing element”.

### CITATION LIST

### Patent Document

Patent Document 1: Japanese Patent Application Publication No. 2005-283451
Patent Document 2: International Publication No. 2016/056135

### BRIEF DESCRIPTION OF THE DRAWINGS

FIG. 1 is a perspective view illustrating an example of a schematic configuration of a current measurement module 100 in a first embodiment.

FIG. 2 is a perspective view illustrating an example of a schematic configuration of a current measurement conductor 10 according to the first embodiment.

FIG. 3 is a perspective view illustrating an example of a schematic configuration of a substrate 20 in the first embodiment.

FIG. 4 illustrates an example of current measurement conductors of cases 1 to 4.

FIG. 5 is a graph illustrating a relationship between a frequency (Hz: horizontal axis) and a magnetic field variation amount (dB: vertical axis).

FIG. 6 is a perspective view illustrating an example of a schematic configuration of a current measurement conductor 200 according to a second embodiment.

FIG. 7 is a perspective view illustrating an example of a schematic configuration of an inverter unit 300 in a third embodiment.

FIG. 8 is a diagram illustrating a magnetic field direction of the inverter unit 300 in the third embodiment.

FIG. 9 is a wiring system diagram of the inverter unit 300 according to the third embodiment.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solving means of the invention.

### Configuration of First Embodiment

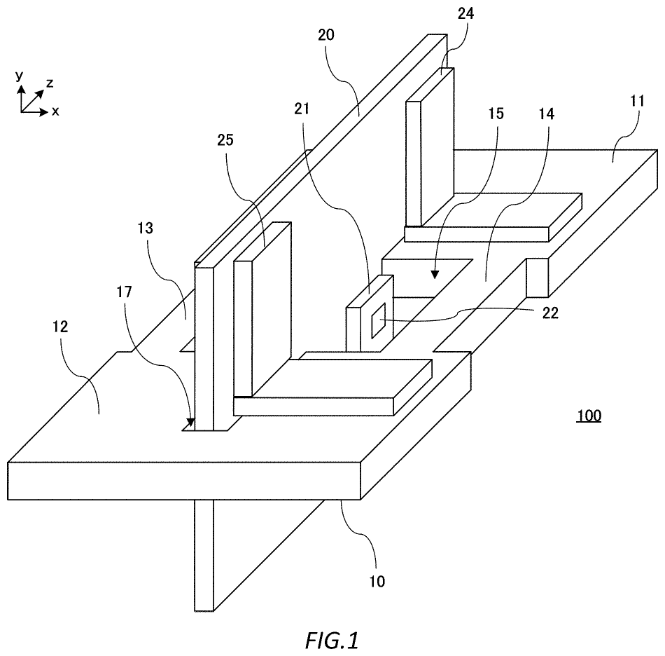

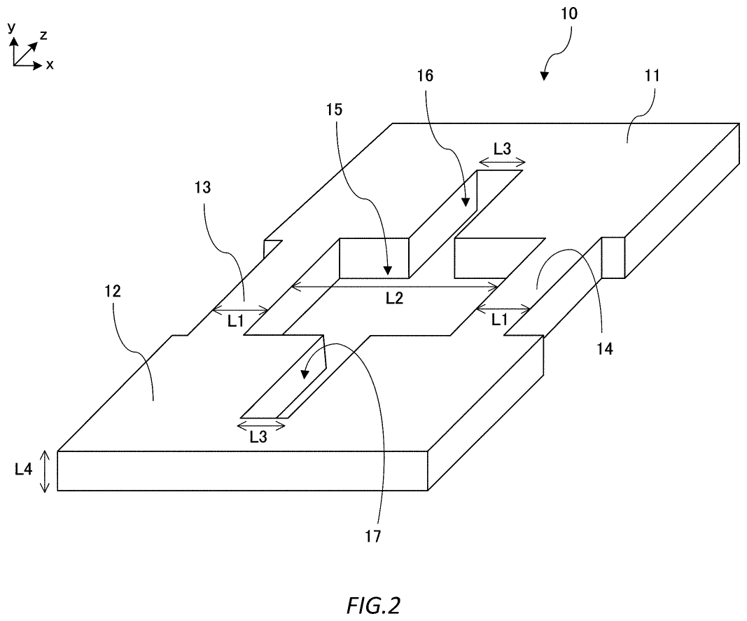

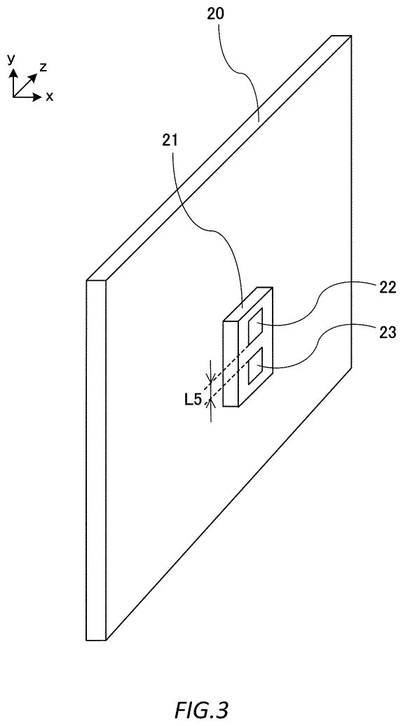

FIG. 1 is a perspective view illustrating an example of a schematic configuration of a current measurement module 100 according to a first embodiment. FIG. 2 is a perspective view illustrating an example of a schematic configuration of a current measurement conductor 10 according to the first embodiment. FIG. 3 is a perspective view illustrating an example of a schematic configuration of a substrate 20 according to the first embodiment. In each drawing, an xyz coordinate system is illustrated. As illustrated in FIG. 1, the current measurement module 100 has a current measurement conductor 10 and the substrate 20.

As illustrated in FIG. 2, the current measurement conductor 10 has two main body portions 11 and 12 and two current paths 13 and 14. The two current paths 13 and 14 are disposed between the two main body portions 11 and 12 and extend in parallel to each other. A gap 15 is disposed between the two current paths 13 and 14. The two main body portions 11 and 12 have slits 16 and 17 extending from the gap 15 and narrower than the gap 15, respectively. Note that the current measurement conductor 10 is also called a bus bar.

In each of the two current paths 13 and 14, a to-be-measured current flows in the same direction. In the present embodiment, the two current paths 13 and 14 are conductors having a rectangular cross-sectional shape and extending linearly. Note that the two current paths 13 and 14 may be configured as conductors having a circular cross-sectional shape and having a linear shape as a whole. The two current paths 13 and 14 are disposed farther inward than the outer edges of the two main body portions 11 and 12 in a direction in which the two current paths 13 and 14 are arranged.

As illustrated in FIG. 2, the two current paths 13 and 14 have respective lengths (cross-sectional widths) L1 in an x direction in the direction in which the two current paths 13 and 14 are arranged. In addition, the gap 15 between the two current paths 13 and 14 has a length L2 in the x direction. In the present embodiment, the length L1 and the length L2 are set so as to satisfy a relationship of length L2≥1.5×length L1 and length L2≤4×length L1. In addition, the two slits 16 and 17 have a length L3 in the x direction. The length L3 is shorter than the length L2. In addition, the current measurement conductor 10 has a length (cross-sectional width) L4 in a y direction.

As illustrated in FIG. 3, two magnetic field sensing elements 22 and 23 are sealed and fixed to the substrate 20 by a package 21. The package 21 is provided with lead terminals for driving the magnetic field sensing elements 22 and 23 and extracting signals from the magnetic field sensing elements 22 and 23. As the package 21, an IC molded package or the like can be used. In the current measurement module 100 illustrated in FIG. 1, the two magnetic field sensing elements 22 and 23 are disposed above and below the gap 15 with the gap interposed therebetween.

Each of the magnetic field sensing elements 22 and 23 detects intensity (magnitude) of the magnetic field generated on each magnetosensitive surface by the to-be-measured current flowing through each of the two current paths 13 and 14, and outputs a detection signal corresponding to the detection intensity. Each of the magnetic field sensing elements 22 and 23 is disposed such that the magnetic fields generated by the to-be-measured currents flowing through the two current paths 13 and 14 in the same direction penetrate the magnetosensitive surface in directions opposite to each other. That is, the magnetic field sensing elements 22 and 23 are disposed such that the directions of the magnetosensitive surfaces coincide with each other between the two current paths 13 and 14. Furthermore, the magnetic field sensing elements 22 and 23 are preferably disposed at symmetrical positions with respect to the current paths 13 and 14. Specifically, the magnetosensitive surface of the magnetic field sensing element 22 and the magnetosensitive surface of the magnetic field sensing element 23 are disposed at equal distances with the plane formed by the current paths 13 and 14 interposed therebetween, and each of the magnetosensitive surfaces of the magnetic field sensing elements 22 and 23 is disposed at the center of the gap between the current path 13 and the current path 14.

In the example of FIG. 3, the direction of the magnetosensitive surface, that is, the normal direction of the surface is a +x direction. The two magnetic field sensing elements 22 and 23 are disposed to be separated by a distance of a length L5 in a direction (y direction) orthogonal to the length direction of the two current paths 13 and 14. In the present embodiment, the length L5 is set so as to satisfy length L5>length L4. By taking a difference between the detection signals obtained by the two magnetic field sensing elements 22 and 23, the magnitudes of the currents flowing through the two current paths 13 and 14 can be measured accurately.

As the magnetic field sensing elements 22 and 23, a magnetoelectric conversion element can be used, and as the magnetoelectric conversion element, for example, a Hall element capable of obtaining a detection signal proportional to the magnitude of a magnetic flux density can be used. Note that as the magnetoelectric conversion element, an MR element (magnetoresistive element), an MI element (magnetic impedance element), or the like may be used in addition to the Hall element. Furthermore, any element in which a detection signal is uniquely determined with respect to an applied magnetic flux density, such as a magnetic sensor IC in which these magnetoelectric conversion elements and IC processing circuit are combined, can be used as the magnetic field sensing elements 22 and 23.

As illustrated in FIG. 1, the substrate 20 supporting the two magnetic field sensing elements 22 and 23 is inserted into the gap 15 in the current measurement conductor 10 and the two slits 16 and 17 extending from the gap 15. The inserted substrate 20 is attached to and fixed to the current measurement conductor 10 by two fixing portions 24 and 25. The fixing portion 24 fixes the substrate 20 to the current measurement conductor 10 at a position corresponding to the slit 16. The fixing portion 25 fixes the substrate 20 to the current measurement conductor 10 at a position corresponding to the slit 17.

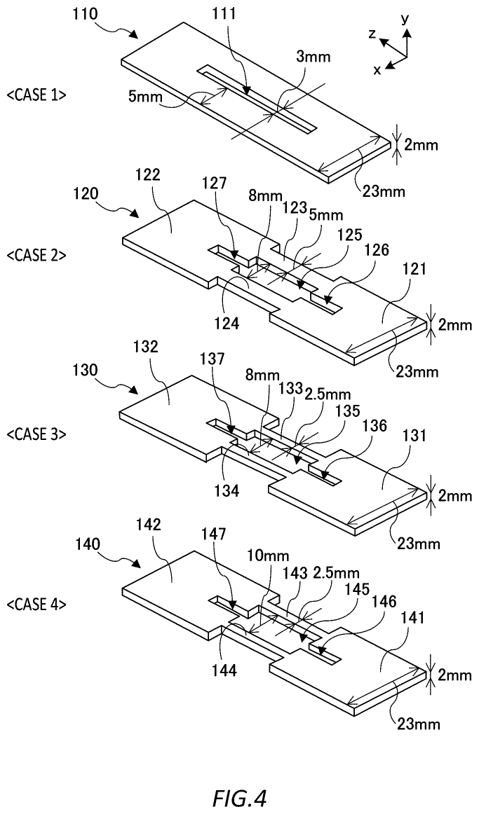

FIG. 4 illustrates current measurement conductors of the cases 1 to 4. The case 1 shows a schematic configuration of a current measurement conductor 110 in a comparative example, the case 2 shows a schematic configuration of a current measurement conductor 120 in a first example, the case 3 shows a schematic configuration of a current measurement conductor 130 in a second example, and the case 4 shows a schematic configuration of a current measurement conductor 140 in a third example. Although not illustrated in FIG. 4, in all the cases, the substrate 20 on which the two magnetic field sensing elements are mounted is disposed in the slit in the central portion of the current measurement conductor. The distance L5 by which the two magnetic field sensing elements are separated in the y direction is 2.5 mm.

The current measurement conductor 110 of the case 1 has a length of 23 mm in the x direction and a length of 2 mm in the y direction, and has a shape extending in the z direction. The current measurement conductor 110 has a slit 111 for inserting the substrate 20 at the central portion. The slit 111 has a length of 3 mm in the x direction. A length between the end portion of the slit 111 in the x direction and the end portion of the current measurement conductor 110 in the x direction is 5 mm.

The current measurement conductor 120 of the case 2 has a length of 23 mm in the x direction and a length of 2 mm in the y direction, and has a shape extending in the z direction. The current measurement conductor 120 has two main body portions 121 and 122 and two current paths 123 and 124. The two current paths 123 and 124 are disposed between the two main body portions 121 and 122 and extend in parallel to each other. A gap 125 is disposed between the two current paths 123 and 124.

The two main body portions 121 and 122 have slits 126 and 127 extending from the gap 125 and narrower than the gap 125, respectively. The substrate 20 of FIG. 1 on which the magnetic field sensing elements are mounted is inserted into the slits 126 and 127. The length L1 of the two current paths 123 and 124 in the x direction is 5 mm, and the length L2 of the gap 125 in the x direction is 8 mm. That is, a relationship of length L2>1.5×length L1 and length L2≤4×length L1 is satisfied.

The current measurement conductor 130 of the case 3 has a length of 23 mm in the x direction and a length of 2 mm in the y direction, and has a shape extending in the z direction. The current measurement conductor 130 has two main body portions 131 and 132 and two current paths 133 and 134. The two current paths 133 and 134 are disposed between the two main body portions 131 and 132 and extend in parallel to each other. A gap 135 is disposed between the two current paths 133 and 134.

The two main body portions 131 and 132 have slits 136 and 137 extending from the gap 135 and narrower than the gap 135, respectively. The substrate 20 of FIG. 1 on which the magnetic field sensing elements are mounted is inserted into the slits 136 and 137. The length L1 of the two current paths 133 and 134 in the x direction is 2.5 mm, and the length L2 of the gap 135 in the x direction is 8 mm. That is, a relationship of length L2>1.5×length L1 and length L2≤4×length L1 is satisfied.

The current measurement conductor 140 of the case 4 has a length of 23 mm in the x direction and a length of 2 mm in the y direction, and has a shape extending in the z direction. The current measurement conductor 140 has two main body portions 141 and 142 and two current paths 143 and 144. The two current paths 143 and 144 are disposed between the two main body portions 141 and 142 and extend in parallel to each other. A gap 145 is disposed between the two current paths 143 and 144.

The two main body portions 141 and 142 have slits 146 and 147 extending from the gap 145 and narrower than the gap 145, respectively. The substrate 20 of FIG. 1 on which the magnetic field sensing elements are mounted is inserted into the slits 146 and 147. The length L1 of the two current paths 143 and 144 in the x direction is 2.5 mm, and the length L2 of the gap 145 in the x direction is 10 mm. That is, a relationship of length L2>1.5×length L1 and length L2≤4×length L1 is satisfied.

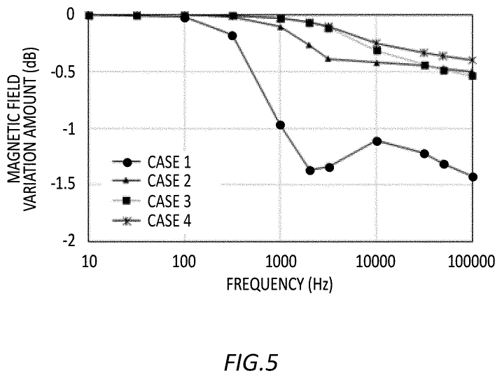

FIG. 5 is a graph illustrating a relationship between a frequency (Hz: horizontal axis) and a magnetic field variation amount (dB: vertical axis) with respect to the current measurement conductors of the cases 1 to 4. The vertical axis represents the magnetic field variation amount based on magnetic field intensity at a frequency of 100 Hz. In FIG. 5, the case 1 is indicated by a round dot, the case 2 is indicated by a triangular dot, the case 3 is indicated by a square, and the case 4 is indicated by a check mark.

In the current measurement conductor 110 in the comparative example illustrated in the case 1, the magnetic field intensity decreases as the frequency increases. This is caused by a skin effect generated in a conductive wire of the current measurement conductor 110. The skin effect refers to a phenomenon in which when an alternating current flows through a conductive wire, the current concentrates on the surface of the conductive wire, and the current becomes less likely to flow as a distance from the surface of the conductive wire increases (that is, as the current approaches the center portion of the conductive wire). The influence of the skin effect increases as the current increases in frequency. When the influence of the skin effect is large, the magnitudes of the to-be-measured currents flowing through the two current paths 13 and 14 cannot be measured accurately.

When a slit is configured to be provided in a plate-shaped bus bar as in the current measurement conductor 110 of the case 1, current density is concentrated on the outer portion of the plate-shaped bus bar. Therefore, when the current flowing through the current measurement conductor 110 increases in frequency, the current path moves away from the magnetic field sensing element disposed in the slit 111 in the central portion, whereby the magnetic field applied to the magnetic field sensing element decreases, and the output of the magnetic field sensing element decreases. Therefore, in the current measurement conductor 110 of the case 1, the magnitude of the to-be-measured current flowing through the current path cannot be measured accurately.

In order to reduce the influence of the skin effect, there are the following two means. First, by decreasing the cross-sectional area of the conductive wire, it is possible to reduce a relative difference of a distance between the magnetic field sensing element and the center of the conductor where the current density decreases with respect to a distance between the magnetic field sensing element and the surface of the conductor where the current density increases, thereby reducing the influence of the skin effect. That is, when the cross-sectional area of the conductive wire is sufficiently small with respect to a skin depth at a frequency at which use is assumed, the current also flows through the vicinity of the center of the conductive wire, which is equivalent to that the influence of the skin effect is not substantially exerted. Second, by increasing a distance between the conductor and the magnetic field sensing element, it is possible to decrease the relative difference of the distance between the magnetic field sensing element and the center of the conductor where the current density decreases with respect to the distance between the magnetic field sensing element and the surface of the conductor where the current density increases, thereby reducing the influence of the skin effect. That is, when a distance between the magnetic field sensing element and the conductive wire is sufficiently long, even if the current flows through the outer side in the conductive wire at a high frequency as compared with that at a low frequency, a difference in the flowing position of the current due to this is relatively small as compared with the distance between the magnetic field sensing element and the conductive wire, and the influence of the skin effect is suppressed.

Using the above two means, in the present embodiment, length L2>1.5×length L1 is satisfied with respect to the length L1 of the two current paths and the length L2 of the gap between the two current paths. Note that when the cross-sectional area of the conductive wire is made excessively small, the amount of current flowing through the conductive wire is limited, and the magnetic field to be detected rather decreases. Therefore, it is desirable to secure the cross-sectional area of the conductive wire to some extent. In addition, when the gap between the two current paths is excessively increased, the current path is separated from the magnetic field sensing element, and the magnetic field to be detected decreases. Furthermore, by increasing the gap between the two current paths, the current measurement conductor is increased, and the size of the current measurement module is also increased. Therefore, the gap between the two current paths is desirably equal to or smaller than a predetermined size. From the above, it is designed to further satisfy length L2≤4×length L1.

In contrast to the current measurement conductor 110 of the case 1, in the current measurement conductor 120 of the first example of the case 2, a decrease in the magnetic field intensity due to an increase in the frequency is suppressed. This is because the cross-sectional areas of the two current paths 123 and 124 decrease so that the influence of the skin effect is reduced. However, in a region where the frequency is 1000 to 10000, the magnetic field intensity slightly decreases.

In the current measurement conductor 130 according to the second example of the case 3, the decrease in the magnetic field intensity due to the increase in the frequency is further suppressed. In particular, the decrease in the magnetic field intensity in the region where the frequency is 1000 to 10000 is suppressed as compared with the current measurement conductor 120 in the case 2. This is because the cross-sectional areas of the two current paths 133 and 134 further decrease so that the influence of the skin effect is further reduced.

In the current measurement conductor 140 according to the third example of the case 4, the decrease in the magnetic field intensity due to the increase in the frequency is further suppressed. In particular, the decrease in the magnetic field intensity in the region where the frequency is 10000 or more is suppressed as compared with the current measurement conductor 130 in the case 3. This is because the influence of the skin effect is reduced by decreasing the cross-sectional area of the two current paths 143 and 144, and increasing the distance between the two current paths 143 and 144 and the magnetic field sensing element by increasing the gap 145 between the two current paths 143 and 144.

From the above, it can be seen that the decrease in the magnetic field intensity due to the increase in the frequency is suppressed in the order of the case 1, the case 2, the case 3, and the case 4. Therefore, it can be seen that the current measurement conductor 110 of the case 1 is most affected by the skin effect, and the current measurement conductor 140 of the case 4 is least affected by the skin effect.

### Effects of First Embodiment

According to the current measurement module 100 in the first embodiment, the two main body portions 11 and 12 have the slits 16 and 17, respectively, and the substrate 20 supporting the two magnetic field sensing elements 22 and 23 is inserted into and fixed to the slits 16 and 17. As a result, the magnitudes of the to-be-measured currents flowing through the two current paths 13 and 14 can be measured with a simple configuration.

According to the current measurement module 100 in the first embodiment, the length L1 of the two current paths 13 and 14 in the x direction and the length L2 of the gap 15 between the two current paths 13 and 14 in the x direction satisfy the relationship of length L2>1.5×length L1 and length L2≤4×length L1. As a result, the influence of the skin effect at the time of current measurement can be reduced, and the magnitudes of the to-be-measured currents flowing through the two current paths 13 and 14 can be measured accurately.

### Configuration of Second Embodiment

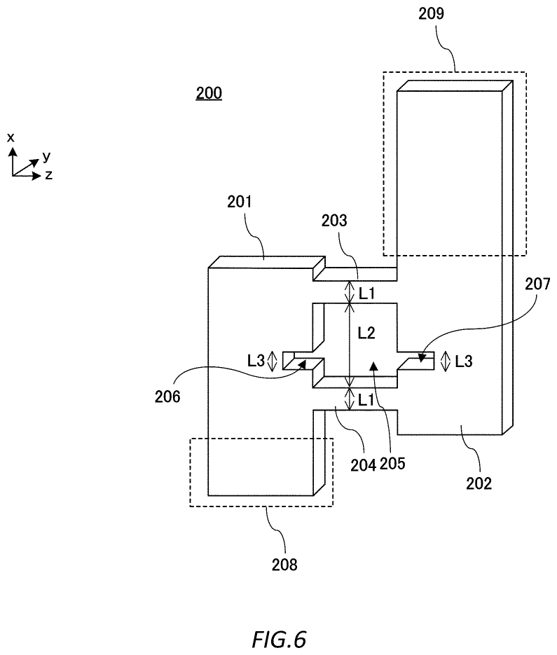

FIG. 6 is a perspective view illustrating an example of a schematic configuration of a current measurement conductor 200 according to the second embodiment. As illustrated in FIG. 6, the current measurement conductor 200 has two main body portions 201 and 202 and two current paths 203 and 204. The two current paths 203 and 204 are disposed between the two main body portions 201 and 202 and extend in parallel to each other. A gap 205 is disposed between the two current paths 203 and 204. The two main body portions 201 and 202 have slits 206 and 207 extending from the gap 205 and narrower than the gap 205, respectively.

In each of the two current paths 203 and 204, a to-be-measured current flows in the same direction. In the present embodiment, the two current paths 203 and 204 are conductors having a rectangular cross-sectional shape and extending linearly. Note that the two current paths 203 and 204 may be configured as conductors having a circular cross-sectional shape and having a linear shape as a whole.

As illustrated in FIG. 6, the two current paths 203 and 204 have a length L1 in the x direction. In addition, the gap 205 between the two current paths 203 and 204 has a length L2 in the x direction. In the present embodiment, the length L1 and the length L2 are set so as to satisfy a relationship of length L2>1.5×length L1 and length L2<4×length L1. In addition, the two slits 206 and 207 have a length L3 in the x direction. The length L3 is shorter than the length L2.

As illustrated in FIG. 6, the two main body portions 201 and 202 have respective extension portions 208 and 209 in which the two main body portions 201 and 202 extend in directions opposite to each other in a direction (x direction) orthogonal to a direction (z direction) in which current flows through the two current paths 203 and 204. That is, the main body portion 201 has the extension portion 208 in which the main body portion 201 extends in the −x direction, and the main body portion 202 has the extension portion 209 in which the main body portion 202 extends in the +x direction.

Each of extension portions 208 and 209 is connected to a terminal of a device on which the current measurement conductor 200 is mounted, whereby the current measurement conductor 200 is mounted on the device. In the second embodiment, as an example, a configuration is made such that the length of the extension portion 208 in the x direction is longer than the length of the extension portion 209 in the x direction. However, the lengths of the extension portions 208 and 209 in the x direction can be appropriately designed according to the configuration of the device on which the current measurement conductor 200 is mounted.

Since the two main body portions 201 and 202 have the respective extension portions 208 and 209, the current measurement conductor 200 can be fixed to the device only by connecting and fixing the extension portions 208 and 209 to the terminal of the device on which the current measurement conductor 200 is mounted, and a structure can be obtained in which assemblability is taken into consideration.

### Effects of Second Embodiment

According to the current measurement conductor 200 in the second embodiment, it is possible to achieve effects similar to those of the current measurement module 100 in the first embodiment.

According to the current measurement conductor 200 in the second embodiment, the two main body portions 201 and 202 have the respective extension portions 208 and 209, so that a structure can be obtained in which assemblability is taken into consideration.

### Configuration of Third Embodiment

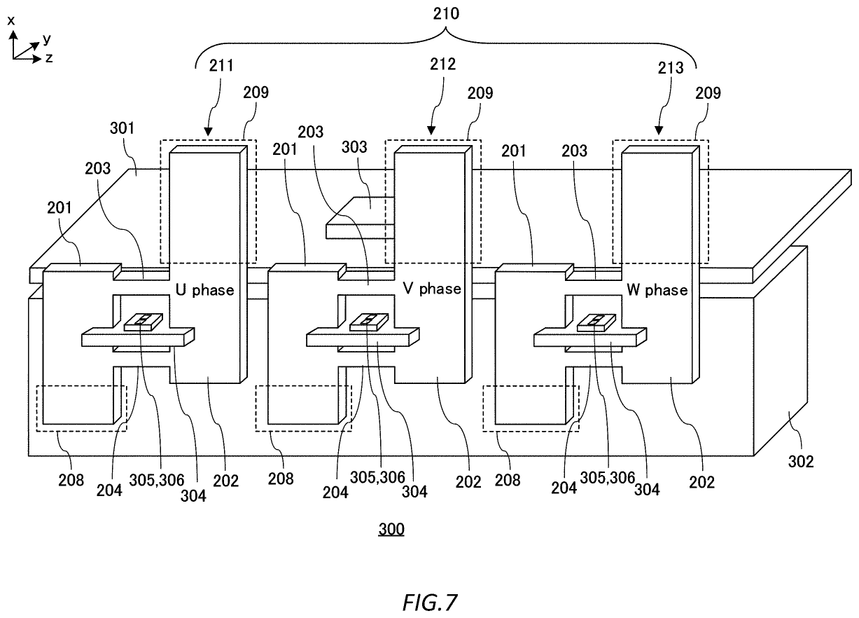

FIG. 7 is a perspective view illustrating an example of a schematic configuration of an inverter unit 300 according to a third embodiment. As illustrated in FIG. 7, the inverter unit 300 according to the third embodiment has a printed circuit board 301, a power module 302, and a current measurement device 210. The current measurement device 210 has three current measurement conductors 211 to 213. The three current measurement conductors 211 to 213 have a configuration similar to that of the current measurement conductor 200 in the second embodiment illustrated in FIG. 6. The three current measurement conductors 211 to 213 are disposed side by side at predetermined intervals in the z direction.

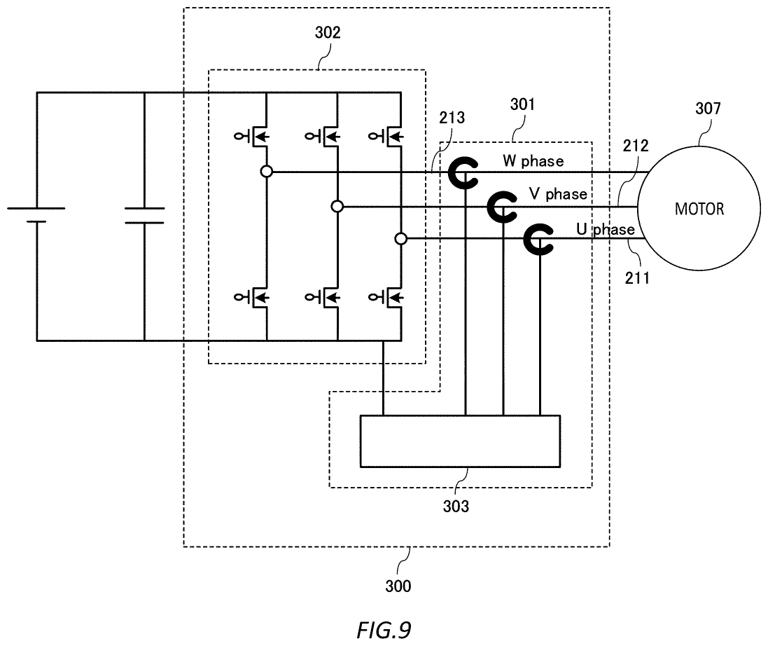

The extension portions 208 of the current measurement conductors 211 to 213 are electrically connected to the power module 302, and the extension portions 209 of the current measurement conductors 211 to 213 are electrically connected to a three-phase motor (a motor 307 in FIG. 9). The left current measurement conductor 211 is a conductor connected to U phase (U terminal) in the three-phase motor, the center current measurement conductor 212 is a conductor connected to V phase (V terminal) in the three-phase motor, and the right current measurement conductor 213 is a conductor connected to W phase (W terminal) in the three-phase motor.

As illustrated in FIG. 7, an electronic component 303 including a control circuit and the like is mounted on the printed circuit board 301. The printed circuit board 301 has three protrusions 304 for fixing the current measurement conductors 211 to 213 to the printed circuit board 301. The protrusion 304 is a part of the printed circuit board 301 protruding in the −y direction. Magnetic field sensing elements 305 and 306 are mounted on the protrusion 304. The protrusion 304 on which the magnetic field sensing elements 305 and 306 are mounted has a configuration similar to that of the substrate 20 on which the magnetic field sensing elements 22 and 23 are mounted in the first embodiment. In the inverter unit 300, the magnetosensitive surfaces of the magnetic field sensing elements 305 and 306 mounted on the protrusion 304 face the +x direction. The magnetic field sensing elements 305 and 306 mounted on the protrusion 304 detect the magnetic fields generated by the to-be-measured currents flowing through the two current paths 203 and 204 in the z direction, thereby detecting the to-be-measured currents flowing through the two current paths 203 and 204.

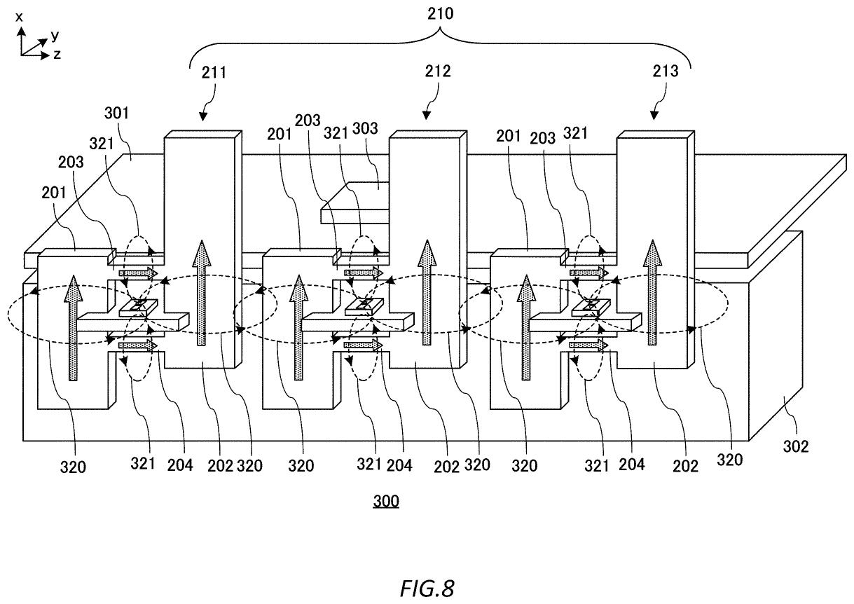

FIG. 8 is a diagram illustrating a magnetic field direction of the inverter unit 300 in the third embodiment. In the inverter unit 300, current flows through the current measurement conductors 211 to 213 in a direction indicated by a hatched arrow. Note that although the current is an alternating current, for the sake of simplicity, a case where the current flows from the main body portion 201 toward the main body portion 202 is illustrated by an arrow. That is, in the two main body portions 201 and 202, the current flows in the x direction, and in the two current paths 203 and 204, the current flows in the z direction. Therefore, the magnetic fields 320 generated by the current flowing through the two main body portions 201 and 202 in the x direction are annular magnetic fields centered on axes parallel to the x axis, and the magnetic fields 321 generated by the to-be-measured current flowing through the two current paths 203 and 204 in the z direction is annular magnetic fields centered on axes parallel to the z axis.

The three current measurement conductors 211 to 213 are disposed at predetermined intervals in a direction parallel to the extending direction of the current paths 203 and 204. As described above, the magnetic fields 320 generated by the current flowing through the main body portions 201 and 202 in the x direction are annular magnetic fields centered on the axes parallel to the x axis, and are orthogonal to the x direction which is the detection direction of the magnetic field sensing elements 305 and 306 (that is, the normal direction of the magnetosensitive surface). Therefore, for example, the magnetic fields 321 detected by the magnetic field sensing elements 305 and 306 of the current measurement conductor 211 can be measured accurately without being affected by the magnetic fields 320 generated from the current flowing through the two main body portions 201 and 202 of each of the current measurement conductor 212 or the current measurement conductor 213 of the adjacent phase.

FIG. 9 is a wiring system diagram of the inverter unit 300 according to the third embodiment. The extension portion 209 of the current measurement conductor 211 is connected to the U phase of the motor 307, the extension portion 209 of the current measurement conductor 212 is connected to the V phase of the motor 307, and the extension portion 209 of the current measurement conductor 213 is connected to the W phase of the motor 307. In addition, the extension portions 208 of the current measurement conductors 211 to 213 are electrically connected to the power module 302. The current measurement device 210 measures the current supplied to the motor 307, and the inverter unit 300 controls the current by the control circuit of the electronic component 303.

When the protrusions 304 are inserted into the three current measurement conductors 211 to 213, the +y side surfaces of the three current measurement conductors 211 to 213 abut on the −y side surface of the printed circuit board 301, whereby the three current measurement conductors 211 to 213 are positioned in the y direction. In this case, when viewed from the x direction, the centers of the two current paths 203 and 204 in the y direction may be located between the magnetic field sensing elements 305 and 306 in the y direction. Furthermore, it is more desirable that the centers of the two current paths 203 and 204 in the y direction be located at the center between the magnetic field sensing elements 305 and 306 in the y direction. With such a design, the three current measurement conductors 211 to 213 can be easily assembled to the inverter unit 300, and errors in the assembly of the three current measurement conductors 211 to 213 to the printed circuit board 301 can be reduced, and thus, a positional relationship between the magnetic field sensing elements 305 and 306 and the three current measurement conductors 211 to 213 can be determined more accurately, and an effect of reducing errors in the output of the magnetic field sensing elements 305 and 306 can be obtained.

### Effects of Third Embodiment

According to the inverter unit 300 in the third embodiment, it is possible to achieve effects similar to those of the current measurement module 100 in the first embodiment and the current measurement conductor 200 in the second embodiment.

According to the inverter unit 300 in the third embodiment, the current measurement device 210 can be mounted on the printed circuit board 301 with a simple configuration, and the inverter unit 300 can be easily assembled.

According to the inverter unit 300 in the third embodiment, the magnetic field sensing elements 305 and 306 of each of the current measurement conductors 211 to 213 is not affected by the magnetic field generated from the current measurement conductor of the adjacent phase, and thus it is possible to perform accurate measurement without receiving noise from the adjacent phase.

In the first to third embodiments, all the current measurement conductors 10 and 200 and 211 and 212 and 213 are formed by punching a copper plate, for example. Note that instead of this, aluminum may be used.

While the present invention has been described with the embodiments, the technical scope of the present invention is not limited to the above-described embodiments. It is apparent to persons skilled in the art that various alterations and improvements can be added to the above-described embodiments. It is also apparent from the description of the claims that the embodiments to which such alterations or improvements are made can be included in the technical scope of the present invention.

The operations, procedures, steps, and stages of each process performed by a device, system, program, and method shown in the claims, specification, or drawings can be performed in any order as long as the order is not indicated by “prior to,” “before,” or the like and as long as the output from a previous process is not used in a later process. Even if the process flow is described using phrases such as “first” or “next” in the claims, specification, or drawings, it does not necessarily mean that the process must be performed in this order.

### EXPLANATION OF REFERENCES

10: current measurement conductor;
11: main body portion;
12: main body portion;
13: current path;
14: current path;
15: gap;
16: slit;
17: slit;
20: substrate;
21: package;
22: magnetic field sensing element;
23: magnetic field sensing element;
24: fixing portion;
25: fixing portion;
100: current measurement module;
110: current measurement conductor;
111: slit;
120: current measurement conductor;
121: main body portion;
122: main body portion;
123: current path;
124: current path;
125: gap;
126: slit;
127: slit;
130: current measurement conductor;
131: main body portion;
132: main body portion;
133: current path;
134: current path;
135: gap;
136: slit;
137: slit;
140: current measurement conductor;
141: main body portion;
142: main body portion;
143: current path;
144: current path;
145: gap;
146: slit;
147: slit;
200: current measurement conductor;
201: main body portion;
202: main body portion;
203: current path;
204: current path;
205: gap;
206: slit;
207: slit;
208: extension portion;
209: extension portion;
210: current measurement device;
211: current measurement conductor;
212: current measurement conductor;
213: current measurement conductor;
300: inverter unit;
301: printed circuit board;
302: power module;
303: electronic component;
304: protrusion;
305: magnetic field sensing element;
306: magnetic field sensing element;
307: motor;
320: magnetic field; and
321: magnetic field.

What is claimed is:

1. A current measurement module comprising:
a conductor which has two main body portions and two current paths disposed between the two main body portions and extending in parallel with a gap;
two magnetic field sensing elements which each have a magnetosensitive surface disposed such that magnetic fields generated by current flowing through the two current paths penetrate the magnetosensitive surface in directions opposite to each other; and
a substrate which supports the two magnetic field sensing elements and is attached to the conductor, wherein
the two main body portions each have a slit which extends from the gap and is narrower than the gap, and
the substrate is inserted into the slit and the gap.

2. The current measurement module according to claim 1, further comprising a fixing portion which fixes the substrate to the two main body portions.

3. The current measurement module according to claim 1, wherein the two current paths are disposed farther inward than outer edges of the two main body portions in a direction in which the two current paths are arranged.

4. The current measurement module according to claim 1, wherein
a cross-sectional width L1 of each of the two current paths in a direction in which the two current paths are arranged, a length L2 of a gap between the two current paths, a cross-sectional width L4 orthogonal to the cross-sectional width L1, and a distance L5 between the two magnetic field sensing elements satisfy
relationships of L2>1.5×L1 and L5>L4.

5. The current measurement module according to claim 4, wherein a relationship of L2≤4×L1 is satisfied.

6. The current measurement module according to claim 1, wherein the two main body portions include extension portions extending in a direction orthogonal to a direction in which current flows through the two current paths, respectively, and the extension portions of the two main body portions extend in directions opposite to each other.

7. A current measurement device comprising the current measurement module according to claim 1.

8. A current measurement conductor comprising:
two main body portions; and
two current paths disposed between the two main body portions and extending in parallel with a gap, wherein
the two main body portions each have a slit which extends from the gap and is narrower than the gap.

9. The current measurement conductor according to claim 8, wherein the two main body portions include extension portions extending in a direction orthogonal to a direction in which current flows through the two current paths, respectively, and the extension portions of the two main body portions extend in directions opposite to each other.

10. A current measurement conductor comprising:
two main body portions; and
two current paths disposed between the two main body portions and extending in parallel with a gap, wherein
the two main body portions include extension portions extending in a direction orthogonal to a direction in which current flows through the two current paths, respectively, and the extension portions of the two main body portions extend in directions opposite to each other.

11. A current measurement module comprising:
the current measurement conductor according to claim 10;
two magnetic field sensing elements which each have a magnetosensitive surface disposed such that magnetic fields generated by current flowing through the two current paths penetrate the magnetosensitive surface in directions opposite to each other; and
a substrate which supports the two magnetic field sensing elements and is attached to the current measurement conductor.

12. The current measurement module according to claim 11, further comprising a fixing portion which fixes the substrate to the two main body portions.

13. The current measurement module according to claim 11, wherein the two current paths are disposed farther inward than outer edges of the two main body portions in a direction in which the two current paths are arranged.

14. The current measurement module according to claim 11, wherein
a cross-sectional width L1 of each of the two current paths in a direction in which the two current paths are arranged, a length L2 of a gap between the two current paths, a cross-sectional width L4 orthogonal to the cross-sectional width L1, and a distance L5 between the two magnetic field sensing elements satisfy
relationships of L2>1.5×L1 and L5>L4.

15. The current measurement module according to claim 14, wherein a relationship of L2≤4×L1 is satisfied.

16. A current measurement device comprising:
a substrate which includes a plurality of protrusions; and
a plurality of current measurement conductors including the current measurement conductor according to claim 10, wherein
each of the plurality of protrusions supports two magnetic field sensing elements and is attached to each of the plurality of current measurement conductors, and
the plurality of protrusions are disposed side by side in a direction parallel to an extending direction of the two current paths in the plurality of current measurement conductors.

17. A current measurement device comprising:
a substrate which includes a plurality of protrusions; and
a plurality of current measurement conductors including the current measurement conductor according to claim 10, wherein
each of the plurality of protrusions supports two magnetic field sensing elements and is attached to each of the plurality of current measurement conductors,
the plurality of protrusions are disposed side by side in a direction parallel to an extending direction of the two current paths in the plurality of current measurement conductors, and
when viewed from a direction in which the extension portions extend, center lines of the two current paths are located between the two magnetic field sensing elements in a state where the substrate and the plurality of current measurement conductors abut on each other.

18. The current measurement device according to claim 17, wherein the two current paths are disposed farther inward than outer edges of the two main body portions in a direction in which the two current paths are arranged.

19. The current measurement device according to claim 17, wherein
a cross-sectional width L1 of each of the two current paths in a direction in which the two current paths are arranged, a length L2 of a gap between the two current paths, a cross-sectional width L4 orthogonal to the cross-sectional width L1, and a distance L5 between the two magnetic field sensing elements satisfy
relationships of L2>1.5×L1 and L5>L4.

20. The current measurement device according to claim 19, wherein a relationship of L2≤4×L1 is satisfied.
